(19) United States
(12) Patent Application Publication
(10) Pub. No.: US 2023/0130079 A1
(43) Pub. Date: Apr. 27, 2023

(54) HIGH VAPOR PRESSURE DELIVERY SYSTEM

(71) Applicant: ENTEGRIS, INC., Billerica, MA (US)

(72) Inventors: Scott L. Battle, Cedar Park, TX (US); John N. Gregg, Marble Falls, TX (US); Donn K. Naito, Meadowlakes, TX (US); Bryan Hendrix, Danbury, CT (US)

(21) Appl. No.: 17/972,242

(22) Filed: Oct. 24, 2022

Related U.S. Application Data
(60) Provisional application No. 63/272,336, filed on Oct. 27, 2021.
(60) Provisional application No. 63/337,782, filed on May 3, 2022.

(51) Int. Cl. C23C 16/448; C23C 16/52

(52) U.S. Cl. CPC C23C 16/448; C23C 16/52

(57) ABSTRACT

A system includes a vaporizer vessel. The vaporizer vessel includes an outlet fluidly connected to the vaporizer vessel. A heater is configured to heat the vaporizer vessel. A valve is configured to regulate a pressure of a vaporized material at the outlet. In response to the pressure at the outlet being outside a set pressure range, the heater is configured to increase or decrease heat to the vaporizer vessel.

### PRIORITY

This disclosure claims priority to U.S. provisional patent No. 63/272,336 with a filing date of Oct. 27, 2021 and U.S. provisional patent No. 63/337,782 with a filing date of May 3, 2022. These priority documents are incorporated by reference.

### FIELD

This disclosure relates generally to a vaporizer. More particularly, this disclosure relates to a vaporizer for vaporization of source reagent materials.

### BACKGROUND

Vaporizers for source reagents generally leverage conductive heating from metallic vessel surfaces to the solid precursor. To disperse heat through the solid precursor, an internal metallic structure can be utilized to provide metallic thermal pathways for the heating.

### SUMMARY

In some embodiments, a system includes a vaporizer vessel. In some embodiments, the vaporizer vessel includes an outlet fluidly connected to the vaporizer vessel. In some embodiments, a heater is configured to heat the vaporizer vessel. In some embodiments, a one or more valves are configured to regulate a pressure of a vaporized material at the outlet. In some embodiments, in response to the pressure at the outlet being outside a set pressure range, the heater is configured to increase or decrease heat to the vaporizer vessel.

In some embodiments, the system includes at least one of a temperature sensor or a pressure sensor in electronic communication with the valve.

In some embodiments, in response to a pressure of the vaporized material being below the set pressure range, the valve is configured to increase the pressure of the vaporized material. In some embodiments, in response to the pressure of the vaporized material being above the set pressure range, the valve is configured to decrease a pressure of the vaporized material.

In some embodiments, in response to the pressure of the vaporized material being below the set pressure range, the heater is configured to increase the heat of the vaporizer vessel. In some embodiments, in response to the pressure of the vaporized material being above the set pressure range, the heater is configured to decrease the heat of the vaporizer vessel.

In some embodiments, in response to the pressure of the vaporized material being above the set pressure range, the heater is disabled.

In some embodiments, the vaporizer vessel is heated to a temperature that is establishes a higher pressure internally at the outlet of the vessel. In such embodiments, the vaporizer vessel may be at a temperature above melting point so that the material has increased thermal contact to the vaporizer vessel. In such embodiments, a valve can decrease the pressure for effective vapor delivery of the material.

In some embodiments, the system includes a second valve disposed in an interior volume of the vaporizer vessel. In some embodiments, in response to the pressure of the vaporized material being below the set pressure range, the second valve is configured to increase the pressure of the vaporized material. In some embodiments, in response to the pressure of the vaporized material being above the set pressure range, the second valve is configured to ‘decrease the pressure of the vaporized material.

In some embodiments the valve may also be placed in the ventilated delivery cabinet and be remotely or directly connected to the vaporizer vessel.

In some embodiments, a system includes a vaporizer vessel. In some embodiments, an outlet is fluidly connected to the vaporizer vessel. In some embodiments, a valve is configured to regulate a pressure of a vaporized material exiting the vaporizer vessel such that the vaporized material is supplied to the outlet within a set pressure range.

In some embodiments, the system includes at least one of a temperature sensor or a pressure sensor in electronic communication with the valve.

In some embodiments, in response to a pressure of the vaporized material being below the set pressure range, the valve is configured to increase the pressure of the vaporized material. In some embodiments, in response to the pressure of the vaporized material being above the set pressure range, the valve is configured to decrease a pressure of the vaporized material.

In some embodiments, the system includes a heater. In some embodiments, in response to the pressure of the vaporized material being below the set pressure range, the heater is configured to increase heat to the vaporizer vessel. In some embodiments, in response to the pressure of the vaporized material being above the set pressure range, the heater is configured to decrease the heat to the vaporizer vessel.

In some embodiments, the system includes a heater. In some embodiments, in response to the pressure being below the set pressure range, the heater is configured to maintain a temperature of the vaporized material. In some embodiments, in response to the pressure being above the set pressure range, the heater is configured to maintain a temperature of the vaporized material.

In some embodiments, the system includes a second valve disposed in an interior volume of the vaporizer vessel. In some embodiments, in response to the pressure of the vaporized material being below the set pressure range, the second valve is configured to increase the pressure of the vaporized material. In some embodiments, in response to the pressure of the vaporized material being above the set pressure range, the second valve is configured to decrease the pressure of the vaporized material.

In some embodiments, a system includes a vaporizer vessel. In some embodiments, an outlet is fluidly connected to the vaporizer vessel. In some embodiments, a heater is configured to heat the vaporizer vessel. In some embodiments, a first valve is configured to regulate a pressure of a vaporized material exiting the vaporizer vessel such that the vaporized material is supplied to the outlet within a first set of pressure range. In some embodiments, a second valve is configured to regulate the pressure of the vaporized material at the outlet such that the vaporized material exits the system within a second set pressure range.

In some embodiments, the system includes at least one of a temperature sensor or a pressure sensor in electronic communication with the second valve.

In some embodiments, in response to the pressure of the vaporized material being below the first set pressure range, the first valve is configured to increase the pressure of the vaporized material. In some embodiments, in response to the pressure of the vaporized material being above the first set pressure range, the first valve is configured to decrease the pressure of the vaporized material.

In some embodiments, in response to the pressure of the vaporized material being below the first set pressure range or the second set pressure range, the heater is configured to increase a temperature of the vaporized material. In some embodiments, in response to the pressure being above the first set pressure range or the second set pressure range, the heater is configured to decrease the temperature of the vaporized material.

In some embodiments, in response to the pressure of the vaporized material being below the first set pressure range or the second set pressure range, the heater is configured to maintain a temperature of the vaporized material. In some embodiments, in response to the pressure of the vaporized material being above the first set pressure range or the second set pressure range, the heater is configured to maintain the temperature of the vaporized material.

In some embodiments, in response to the pressure of the vaporized material being below the second set pressure range, the second valve is configured to increase the pressure of the vaporized material. In some embodiments, in response to the pressure of the vaporized material being above the second set pressure range, the second valve is configured to decrease the pressure of the vaporized material.

In some embodiments, the first valve is a mechanical valve and the second valve is an electronically actuated valve.

In some embodiments, the second set pressure range is a narrower range of pressures than the first set pressure range.

### BRIEF DESCRIPTION OF THE DRAWINGS

References are made to the accompanying drawings that form a part of this disclosure and that illustrate embodiments in which the systems and methods described in this Specification can be practiced.

FIG. 1 is a schematic diagram of a vaporizer system, according to some embodiments.

FIG. 2 is a flowchart of a method for controlling a vaporizer system, according to some embodiments.

FIG. 3 is a flowchart of a method for controlling a vaporizer system, according to some embodiments.

FIG. 4 is a flowchart of a method for controlling a vaporizer system, according to some embodiments.

FIG. 5 is a flowchart of a method for controlling a vaporizer system, according to some embodiments.

Like reference numbers represent the same or similar parts throughout.

### DETAILED DESCRIPTION

Embodiments of this disclosure relate to a vaporizer, systems, and methods for volatilization of source reagents to produce vapor for fluid-utilizing processes such as chemical vapor deposition (CVD) processes, atomic layer deposition (ALD) processes, plasma-enhanced atomic layer deposition (PEALD) processes, metal organic chemical vapor deposition (MOCVD) processes, plasma-enhanced chemical vapor deposition (PECVD) processes, and the like.

Embodiments of this disclosure can be applied with various types of source reagents, including solid form source reagent materials, liquid form source reagent materials, semi-solid from source reagent materials, slurry form source reagent materials (including solid materials suspended in a liquid), and solutions of solid materials dissolved in a solvent. In some embodiments, solid form source reagent materials may, for example, be in the form of powders, granules, pellets, beads, bricks, blocks, sheets, rods, plates, films, coatings, or the like, and may embody porous or nonporous forms, as desirable in a given application.

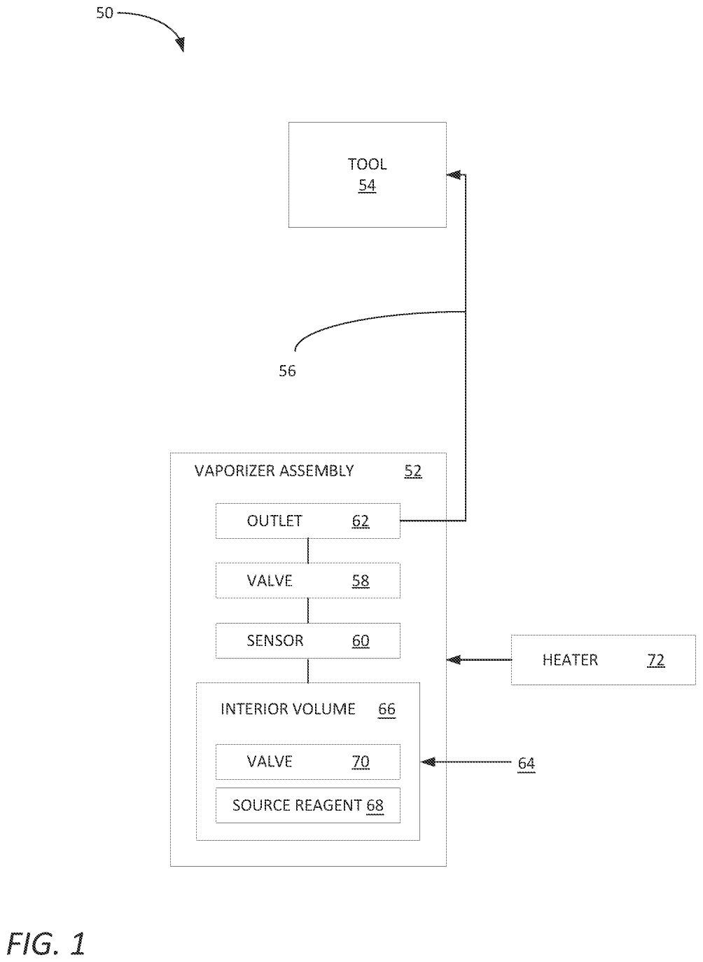

FIG. 1 is a schematic diagram of a vaporizer system 50, according to some embodiments.

The vaporizer system 50 generally includes a vaporizer assembly 52 and a tool 54 fluidly connected by a conduit 56. A valve 58 and a sensor 60 are fluidly disposed prior to an outlet 62 of the vaporizer assembly 52.

The vaporizer assembly 52 can be used to deliver a vaporized source reagent in, for example, chemical vapor deposition (CVD) processes, atomic layer deposition (ALD) processes, plasma-enhanced atomic layer deposition (PEALD) processes, metal organic chemical vapor deposition (MOCVD) processes, and plasma-enhanced chemical vapor deposition (PECVD) processes. It is to be appreciated that these applications are examples and that additional uses for the vaporizer assembly 52 are possible within the scope of the present disclosure.

The vaporizer assembly 52 includes a vaporizer vessel 64. The vaporizer vessel 64 includes an interior volume 66. The interior volume 66 holds a source reagent 68. In some embodiments, a valve 70 is disposed within the interior volume 66. The source reagent 68 as heated can be provided via an outlet from the vaporizer vessel 64 as a vaporized source reagent.

In some embodiments, the vaporizer vessel 64 is formed of a heat-conducting material. In some embodiments, the heat-conducting material can be, but is not limited to, silver, silver alloy, copper, copper alloy, aluminum, aluminum alloy, lead, nickel clad, stainless steel, graphite, silicon carbide coated graphite, boron nitride, ceramic material, any combination thereof, or the like. The vaporizer vessel 64 can have any shape. In some embodiments, the vaporizer vessel 64 can be cylindrical in shape.

It is to be appreciated that the vaporizer vessel 64 can include additional elements such as, but not limited to, a carrier gas inlet for providing a gas that will support the vaporized source reagent and an outlet for the vaporized source reagent.

One or more additional structures can be included for the purpose of holding the source reagent 68 in the interior volume 66. In some embodiments, the interior volume 66 can include a thermally absorbent material that is in contact with the source reagent 68 to provide conductive heat to the source reagent 68.

In some embodiments, the vaporizer assembly 52 can additionally include lines for supplying a carrier gas to the vaporizer vessel 64; lines for discharging source reagent 68 vapor from the vaporizer vessel 64; flow circuitry components such as flow control valves, mass flow controllers, regulators, restricted flow orifice elements, thermocouples, pressure transducers, monitoring and control devices, heaters for input of thermal energy to the vaporizer vessel and its contents, heaters for maintaining temperature in the carrier gas supply lines and source reagent vapor discharge lines, any combination thereof, or the like.

The source reagent 68 can include precursors of any suitable type. Examples of such precursors include, but are not limited to, solid-phase metal halides, organometallic solids, any combination thereof, or the like. Examples of the source reagent 68 that may be utilized include, but are not limited to, dimethyl hydrazine, trimethyl aluminum (TMA), hafnium chloride (HfCl₄), zirconium chloride (ZrCl₄), indium trichloride, aluminum trichloride, titanium iodide, tungsten carbonyl, Ba(DPM)₂, bis di pivaloyl methanato strontium (Sr(DPM)₂), TiO(DPM)₂, tetra di pivaloyl methanato zirconium (Zr(DPM)₄), decaborane, boron, magnesium, gallium, indium, antimony, copper, phosphorous, arsenic, lithium, sodium tetrafluoroborates, precursors incorporating alkyl-amidinate ligands, organometallic precursors, zirconium tertiary butoxide (Zr (t-OBu)₄), tetrakisdiethylaminozirconium (Zr(Net₂)₄), tetrakisdiethylaminohafnium (Hf(Net₂)₄), tetrakis(dimethylamino)titanium (TDMAT), tertbutyliminotris(deithylamino)tantalum (TBTDET), pentakis(demethylamino)tantalum (PDMAT), pentakis(ethylmethylamino)tantalum (PEMAT), tetrakisdimethylaminozirconium (Zr(NMe₂)₄), hafniumtertiarybutoxide (Hf(tOBu)₄), xenon difluoride (XeF₂), xenon tetrafluoride (XeF₄), xenon hexafluoride (XeF₆), formations of molybdenum including, but not limited to, MoO₂Cl₂, MoO₂, MoOCl₄, MoCl₅, Mo(CO)₆, formations of tungsten including, but not limited to, WCl₅ and WCl₆, W(CO)₆, and compatible combinations and mixtures of two or more of the foregoing.

Other source reagents can be used. For example, in some embodiments, the source reagent includes at least one of dimethyl hydrazine, trimethyl aluminum (TMA), hafnium chloride (HfCl₄), zirconium chloride (ZrCl₄), indium trichloride, indium monochloride, aluminum trichloride, titanium iodide, tungsten carbonyl, Ba(DPM)₂, bis dipivaloyl methanato strontium (Sr(DPM)₂), TiO(DPM)₂, tetra dipivaloyl methanato zirconium (Zr(DPM)₄), decaborane, octadecaborane, boron, magnesium, gallium, indium, antimony, copper, phosphorous, arsenic, lithium, sodium tetrafluoroborates, precursors incorporating alkyl-amidinate ligands, organometallic precursors, zirconium tertiary butoxide (Zr(t-OBu)₄), tetrakisdiethylaminozirconium (Zr(NEt₂)₄), tetrakisdiethylaminohafnium (Hf(NEt₂)₄), tetrakis(dimethylamino)titanium (TDMAT), tertbutyliminotris(diethylamino)tantalum (TBTDET), pentakis(dimethylamino)tantalum (PDMAT), pentakis(ethylmethylamino)tantalum (PEMAT), tetrakisdimethylaminozirconium (Zr(NMe₂)₄), hafniumtertiarybutoxide(Hf(tOBu)₄), xenon difluoride (XeF₂), xenon tetrafluoride (XeF₄), xenon hexafluoride (XeF₆), or any combination thereof.

In some embodiments, the source reagent includes at least one of decaborane, hafnium tetrachloride, zirconium tetrachloride, indium trichloride, metalorganic (3-diketonate complexes, tungsten hexafluoride, cyclopentadienylcycloheptatrienyl-titanium (CpTiCht), aluminum trichloride, titanium iodide, cyclooctatetraenecyclo-pentadienyltitanium, biscyclopentadienyltitaniumdiazide, trimethyl gallium, trimethyl indium, aluminum alkyls like trimethylaluminum, triethylaluminum, trimethylamine alane, dimethyl zinc, tetramethyl tin, trimethyl antimony, diethyl cadmium, tungsten carbonyl, or any combination thereof.

In some embodiments, the source reagent includes elemental metal, metal halides, metal oxyhalides, metalorganic complexes, or any combination thereof. For example, in some embodiments, the source reagent includes at least one of elemental boron, copper, phosphorus, decaborane, gallium halides, indium halides, antimony halides, arsenic halides, gallium halides, aluminum iodide, titanium iodide, MoO₂Cl₂, MoOCl₄, MoCl₅, WCl₅, WOCl₄, WCl₆, cyclopentadienylcycloheptatrienyltitanium (CpTiCht), cyclooctatetraenecyclopenta-dienyltitanium, biscyclopentadienyltitanium-diazide, In(CH₃)₂(hfac), dibromomethyl stibine, tungsten carbonyl, metalorganic β-diketonate complexes, metalorganic alkoxide complexes, metalorganic carboxylate complexes, metalorganic aryl complexes, metalorganic amido complexes, or any combination thereof.

In some embodiments, the source reagent includes at least one of decaborane, (B₁₀H₁₄), pentaborane (B₅H₉), octadecaborane (B₁₈H₂₂), boric acid (H₃BO₃), SbCl₃, SbCl₅, or any combination thereof. In some embodiments, the source reagent includes at least one of at least one of AsCl₃, AsBr₃, AsF₃, AsF₃, AsH₃, As₄O₆, As₂Se₃, As₂S₂, As₂S₃, As₂S₅, As₂Te₃, B₄H₁₁, B₄H₁₀, B₃H₆N₃, BBr₃, BCl₃, BF₃, BF₃.O(C₂H₅)₂, BF₃.HOCH₃, B₂H₆, F₂, HF, GeBr₄, GeCl₄, GeF₄, GeH₄, H₂, HCl, H₂Se, H₂Te, H₂S, WF₆, SiH₄, SiH₂Cl₂, SiHCl₃, SiCl₄, SiH₃Cl, NH₃, NH₃, Ar, Br₂, HBr, BrF₅, CO₂, CO, COCl₂, COF₂, Cl₂, ClF₃, CF₄, C₂F₆, C₃F₈, C₄F₈, C₅F₈, CHF₃, CH₂F₂, CH₃F, CH₄, SiH₆, He, HCN, Kr, Ne, Ni(CO)₄, HNO₃, NO, N₂, NO₂, NF₃, N₂O, C₈H₂₄O₄Si₄, PH₃, POCl₃, PCl₅, PF₃, PFS, SbH₃, SO₂, SF₆, SF₄, Si(OC₂H₅)₄, C₄Hi₆Si₄O₄, Si(CH₃)₄, SiH(CH₃)₃, TiCl₄, Xe, SiF₄, WOF₄, TaBr₅, TaCl₅, TaF₅, Sb(C₂H₅)₃, Sb(CH₃)₃, In(CH₃)₃, PBr₅, PBr₃, RuF₅, or any combination thereof. It will be appreciated that other source reagents may be used herein without departing from this disclosure.

As an illustrative example selected from among the foregoing materials, hafnium chloride is a source reagent that is utilized to achieve deposition of hafnium and hafnium-containing films in semiconductor manufacturing operations.

A heater 72 can be in thermal communication with the vaporizer assembly 52, in some embodiments. In such embodiments, the heater 72 can heat the vaporizer vessel 64 and can be conducted in any suitable manner. In one embodiment, a ribbon heater is wound around the vaporizer vessel 64. In another embodiment, a block heater having a shape covering at least a major portion of the external surface of the vaporizer vessel 64 is employed to heat the vaporizer vessel 64. In still another embodiment, a heat transfer fluid at elevated temperature may be contacted with the exterior surface of the vaporizer vessel 64, to effect heating thereof. A further embodiment involves heating by infrared or other radiant energy being impinged on the vaporizer vessel 64.

The method of heating of the vaporizer vessel 64 with heater 72 is not particularly limited as long as the vaporizer vessel 64 is brought thereby to a desired temperature level and maintained at such temperature level in an accurate and reliable manner.

The amount of heat supplied by the heater 72 to the vaporizer assembly 52 can depend on the source reagent being employed (e.g., sublimination point, vaporization point, etc.), the parameters under which the vaporizer system is operating (e.g., mass flow rate, volumetric flow rate, etc.), and the conditions under which the vaporizer system is operating (e.g., temperature, pressure, etc.), among other things. For example, in some embodiments, the amount of heat supplied by the heater 72 to the vaporizer assembly 52 can be modulated or tailored to the specific properties of the source reagent, under the conditions and parameters under which the vaporizer system is being operated.

The vaporizer vessel 64 is in fluid communication with a tool 54. The tool 54 can be representative of various manufacturing tools such as, but not limited to, those used in semiconductor manufacturing processes. The tool 54 can use the vaporized source reagent in the manufacturing process. Generally, the tool 54 may include one or more requirements at which the pressure of the vaporized source reagent is to be received. For example, the tool 54 may require the vaporized source reagent to be delivered at a subatmospheric pressure, at about atmospheric pressure, above atmospheric pressure, or at a superatmospheric pressure.

In some embodiments, the sensor 60 can be a device capable of sensing a characteristic of the source reagent 68. In some embodiments, the characteristic can include a pressure of the source reagent 68; a temperature of the source reagent 68; a mass flow rate of the source reagent 68; any combination thereof; or the like. In some embodiments, the sensor 60 is a temperature sensor configured to measure a temperature of the source reagent 68. In such embodiments, the temperature can be used to determine a pressure of the source reagent 68. In some embodiments, the sensor 60 can be a pressure sensor configured to measure a pressure of the source reagent 68. In some embodiments, the sensor 60 can be used to determine whether the source reagent 68 is within a pressure range required by the tool 54. In some embodiments, in response to determining the pressure is outside the pressure range, an action can be taken to increase the pressure of the source reagent 68 provided to the tool 54. In some embodiments, the action can include modifying a state of the valve 58; modifying a state of the valve 70; modifying a setpoint temperature of the heater 72; or any combination thereof.

An additional sensor may be located with the tool 54. The additional sensor may provide feedback to control the valve 58. The additional sensor may be located before the outlet 62. The additional sensor may be a temperature sensor, a pressure sensor, a flow sensor, and/or other type of sensor to monitor the amount of source reagent converted to vapor and provided at the outlet 62 to the tool 54. The additional sensor may work with sensor 60 to provide control to the system. In some embodiments, the additional sensor is optional.

In some embodiments, the valve 58 can include an electronically actuatable valve. For example, in some embodiments, the valve 58 can be selectively opened/closed to control an output pressure from the valve 58 based on a pressure setting. In some embodiments, the valve 58 can have a variable orifice that is selectively set to control the output pressure from the valve 58 based on the pressure setting. In some embodiments, the valve 58 can be a mechanical valve. For example, in some embodiments, the valve 58 can be a fixed orifice valve configured to output a selected pressure. In some embodiments, the valve 58 can be used to control the pressure of the source reagent 68 exiting the outlet 62 to be within a set pressure range. In some embodiments, the set pressure range can be based on a pressure range required by the tool 54.

In some embodiments, the valve 70 can include an electronically actuatable valve. For example, in some embodiments, the valve 70 can be selectively opened/closed to control an output pressure from the valve 70 based on a pressure setting. In some embodiments, the valve 70 can have a variable orifice that is selectively set to control the output pressure from the valve 70 based on the pressure setting. In some embodiments, the valve 70 can be a mechanical valve. For example, in some embodiments, the valve 70 can be a fixed orifice valve configured to output a selected pressure. In such embodiments, the valve 70 can be used collectively with the valve 58 to provide the source reagent 68 that is within the pressure range required by the tool 54. In some embodiments, the valve 70 can be used to control the pressure of the source reagent 68 exiting the interior volume 66 to be within a set pressure range. In some embodiments, the set pressure range exiting the interior volume 66 can be greater than the set pressure range exiting the outlet (e.g., for valve 58) and can be based on a pressure range required by the tool 54.

In some embodiments, the valve 58 can be included in the vaporizer system 50 without the valve 70 being included in the vaporizer system 50. In some embodiments, the valve 70 can be included in the vaporizer system 50 without the valve 58 being included in the vaporizer system 50. In some embodiments, the valve 58 and the valve 70 can be included in the vaporizer system 50.

In some embodiments, the valve 58 provides a fine control over the pressure of the source reagent 68 and the valve 70 provides a broader control over the pressure of the source reagent 68. For example, in some embodiments, the valve 70 can be set to have a first set pressure range and the valve 58 can be set to have a second set pressure range. The second set pressure range can be narrower than the first set pressure range. As a result, the valve 70 can be used to control the pressure of the source reagent 68 to be within the first set pressure range, and the valve 58 can then be used to control the pressure of the source reagent 68 to be within the second set pressure range. In such embodiments, the second set pressure range is within the first set pressure range. In this manner, in some embodiments, the valve 58 and the valve 70 can work together to control the pressure of the source reagent 68. In some embodiments, the second set pressure range can overlap with the first set pressure range but may not be entirely encompassed by the first set pressure range.

In some embodiments, the invention as described provides the capability to maintain and stabilize the output pressure range as the source reagent is vaporized, by controlling source reagent at a higher thermal contact and controlling the outset temperature the invention allows the full utilization and effective vaporization of the source reagent. That can be at 95, 98, 99, 99.5 percent utilization of the source reagent in the vessel.

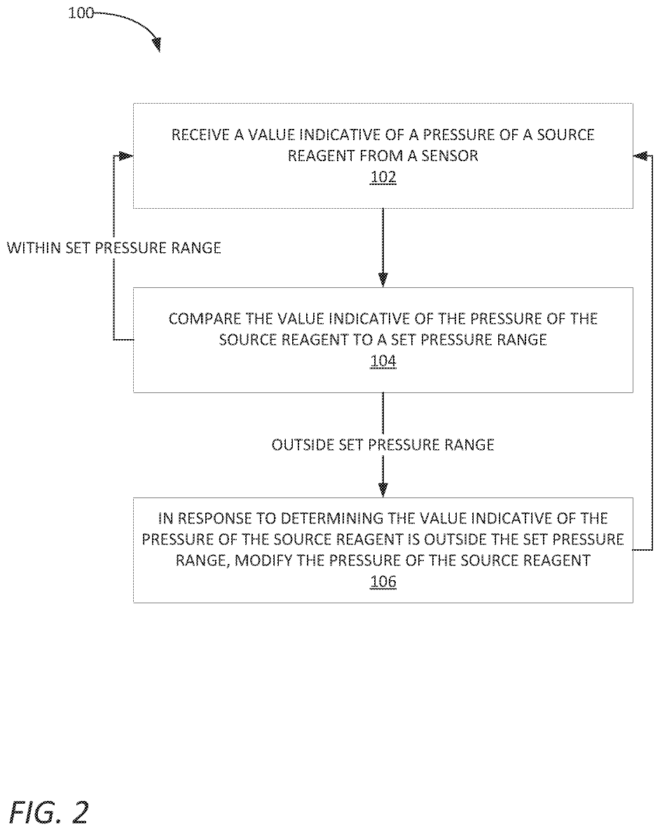

FIG. 2 shows a method 100, according to some embodiments. The method 100 can generally be used to control an outlet pressure of the source reagent 68 (FIG. 1) from the vaporizer system 50 (FIG. 1).

At block 102, the method 100 includes receiving, by a processor, a value indicative of a pressure of the source reagent from a sensor. In some embodiments, the sensor can be a pressure sensor. In such embodiments, the value indicative of the pressure of the source reagent can be directly received. In some embodiments, the sensor can be a sensor other than a pressure sensor. For example, in some embodiments, the sensor can be a temperature sensor. In such embodiments, a pressure can be computed by a processor based on the temperature.

At block 104, the method 100 includes comparing, by a processor, the value indicative of the pressure of the source reagent 68 to a set pressure range.

At block 106, in response to determining the pressure value is outside the set pressure range, the method 100 includes modifying a pressure of the source reagent 68.

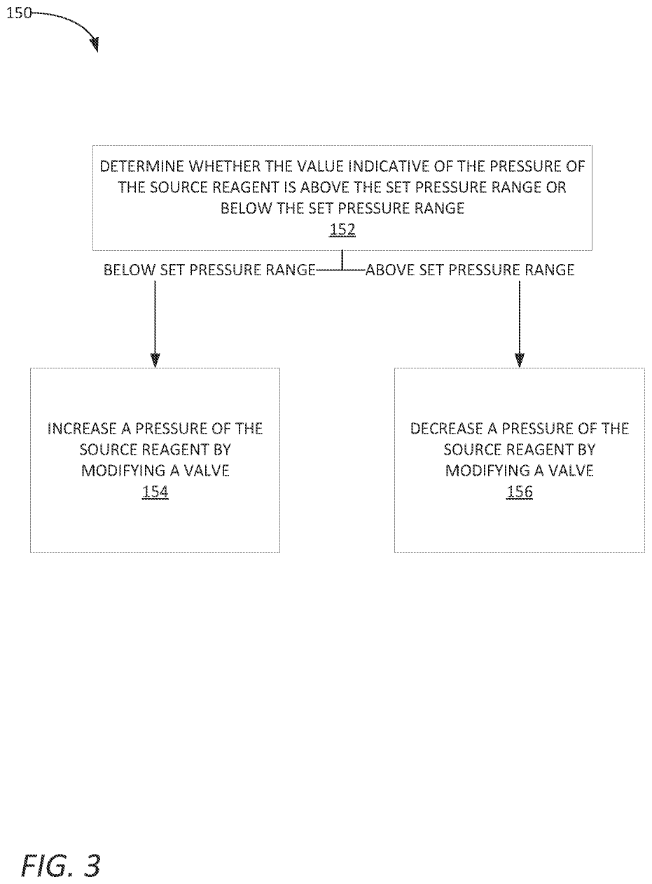

The method 100 can repeat while the vaporizer system 50 is operational. That is, as the pressure is modified at block 106, the method repeats block 102 and continues to monitor the pressure to ensure the delivery pressure of the source reagent 68 is within the set pressure range. The methods of FIGS. 3-5 can be used to modify the pressure of the source reagent 68 at block 106.

FIG. 3 shows a method 150, according to some embodiments. The method 150 can generally be used to modify an outlet pressure of the source reagent 68 (FIG. 1) from the vaporizer system 50 (FIG. 1) such as at block 106 of FIG. 2.

At block 152, the processor determines whether the value indicative of the pressure of the source reagent 68 is above the set pressure range or below the set pressure range.

At block 154, in response to determining the value indicative of the pressure of the source reagent 68 is below the set pressure range, the method 150 includes modifying the valve 58 to increase a pressure of the source reagent 68 from the outlet 62. In some embodiments, modifying the valve 58 includes increasing a flow through the valve 58. In some embodiments, this can include, for example, increasing an aperture size through which the source reagent 68 flows in the valve 58. In some embodiments, this can include opening the valve 58 for a longer period of time. In some embodiments, the specific control for the valve 58 depends on the type of the valve 58.

At block 156, in response to determining the value indicative of the pressure of the source reagent 68 is above the set pressure range, the method 150 includes modifying the valve 58 to decrease a pressure of the source reagent 68 from the outlet 62. In some embodiments, modifying the valve 58 includes decreasing a flow through the valve 58. In some embodiments, this can include, for example, decreasing an aperture size through which the source reagent 68 flows in the valve 58. In some embodiments, this can include closing the valve 58 for a longer period of time. In some embodiments, the specific control for the valve 58 depends on the type of the valve 58.

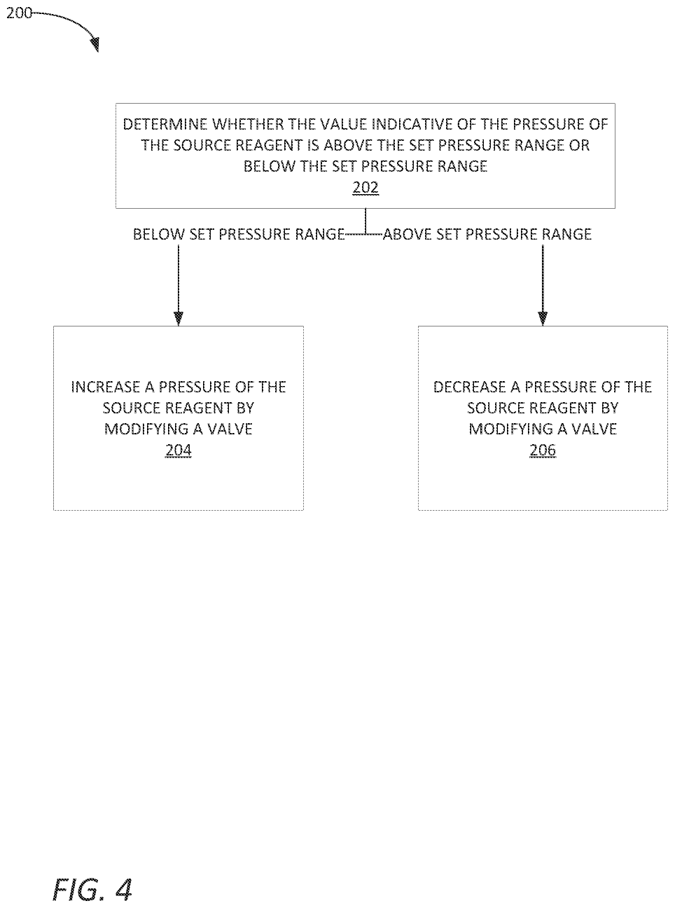

FIG. 4 shows a method 200, according to some embodiments. The method 200 can generally be used to modify an outlet pressure of the source reagent 68 (FIG. 1) from the vaporizer system 50 (FIG. 1) such as at block 106 of FIG. 2.

At block 202, the processor determines whether the value indicative of the pressure of the source reagent 68 is above the set pressure range or below the set pressure range.

At block 204, in response to determining the value indicative of the pressure of the source reagent 68 is below the set pressure range, the method 200 includes modifying the valve 70 to increase a pressure of the source reagent 68 from the outlet 62. In some embodiments, modifying the valve 70 includes increasing a flow through the valve 70. In some embodiments, this can include, for example, increasing an aperture size through which the source reagent 68 flows in the valve 70. In some embodiments, this can include opening the valve 70 for a longer period of time. In some embodiments, the specific control for the valve 70 depends on the type of the valve 70.

At block 206, in response to determining the value indicative of the pressure of the source reagent 68 is above the set pressure range, the method 200 includes modifying the valve 70 to decrease a pressure of the source reagent 68 from the outlet 62. In some embodiments, modifying the valve 70 includes decreasing a flow through the valve 70. In some embodiments, this can include, for example, decreasing an aperture size through which the source reagent 68 flows in the valve 70. In some embodiments, this can include closing the valve 70 for a longer period of time. In some embodiments, the specific control for the valve 70 depends on the type of the valve 70.

In some embodiments, the method 200 and the method 150 (FIG. 3) can be collectively performed at block 106 (FIG. 2).

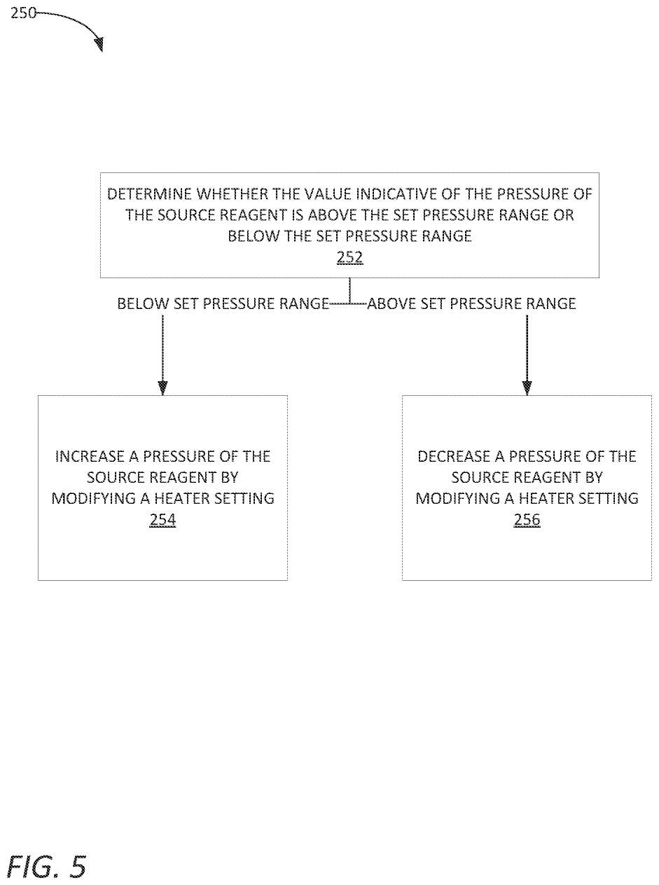

FIG. 5 shows a method 250, according to some embodiments. The method 250 can generally be used to modify an outlet pressure of the source reagent 68 (FIG. 1) from the vaporizer system 50 (FIG. 1) such as at block 106 of FIG. 2.

At block 252, a processor determines whether the value indicative of the pressure of the source reagent 68 is above the set pressure range or below the set pressure range.

At block 254, in response to determining the value indicative of the pressure of the source reagent 68 is below the set pressure range, the method 250 includes modifying the settings of the heater 72 to increase a pressure of the source reagent 68 from the outlet 62. In some embodiments, modifying the settings of the heater 72 can include increasing a setpoint temperature of the heater 72. In some embodiments, modifying the settings of the heater 72 can include increasing a time period in which the heater 72 is enabled or heating.

At block 256, in response to determining the value indicative of the pressure of the source reagent 68 is above the set pressure range, the method 150 includes modifying the settings of the heater 72 to decrease a pressure of the source reagent 68 from the outlet 62. In some embodiments, modifying the settings of the heater 72 can include decreasing a setpoint temperature of the heater 72. In some embodiments, modifying the settings of the heater 72 can include decreasing a time period in which the heater 72 is enabled or heating.

In some embodiments, the method 250, the method 150 (FIG. 3), and the method 200 (FIG. 4) can be collectively performed at block 106 (FIG. 2). In some embodiments, the method 250 and the method 150 or the method 200 can be collectively performed at block 106.

In some embodiments, the vaporizer vessel is heated to a temperature that establishes a higher pressure internally compared to the outlet of the vessel. For example, the temperature internally can range from, but not limited to, 150-300 degrees Celsius, or may be above the boiling point of the liquid, so that the pressure internally can range above atmospheric pressure. The control valve, which can be located internally, externally or in the ventilated heated cabinet, can adjust the pressure to a standard 600 Torr or a desired lower pressure, or even more so that the vapor at the outlet is delivered at atmospheric pressure. This embodiment can be used for all source reagents described herein.

A specific example is MoO₂Cl₂. It can be held in a vessel above the melting point of 177° C., so that the vapor pressure above the liquid will be above atmospheric pressure. The liquid maintains intimate thermal contact with the ampoule and so maintains a high vapor pressure. Then a control valve in the ampoule or in the cabinet can keep the pressure exiting the cabinet in a desired range. For example, the pressure can be kept below 600 Torr for delivery below atmospheric pressure. Alternatively, pressure can be maintained in a narrow range, in order to control flow through affixed orifice.

A second example of conditions for a vaporizer vessel containing and delivering MoO2Cl2 is as follows. If the desired delivery pressure is 100 Torr (in equilibrium with solid at about 140° C.), the vessel; can be held at a constant 155° C. This will create a pressure in the ampoule of about 220 Torr when there is no flow. As flow is established and the control valve adjusts to keep outlet pressure at 100 Torr, the material in the vessel can cool as much as 15° C. under the dynamic conditions without compromising the outlet pressure

The terminology used herein is intended to describe embodiments and is not intended to be limiting. The terms “a,” “an,” and “the” include the plural forms as well, unless clearly indicated otherwise. The terms “comprises” and/or “comprising,” when used in this Specification, specify the presence of the stated features, integers, steps, operations, elements, and/or components, but do not preclude the presence or addition of one or more other features, integers, steps, operations, elements, and/or components.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A system, comprising:
a vaporizer vessel;
an outlet fluidly connected to the vaporizer vessel;
a heater configured to heat the vaporizer vessel; and
a valve configured to regulate a pressure of a vaporized material at the outlet;
wherein, in response to the pressure at the outlet being outside a set pressure range, the heater is configured to increase or decrease heat to the vaporizer vessel.

2. The system of claim 1, further comprising at least one of a temperature sensor or a pressure sensor in electronic communication with the valve.

3. The system of claim 1,
wherein, in response to a pressure of the vaporized material being below the set pressure range, the valve is configured to increase the pressure of the vaporized material;
wherein, in response to the pressure of the vaporized material being above the set pressure range, the valve is configured to decrease a pressure of the vaporized material.

4. The system of claim 3,
wherein, in response to the pressure of the vaporized material being below the set pressure range, the heater is configured to increase the heat of the vaporizer vessel;
wherein, in response to the pressure of the vaporized material being above the set pressure range, the heater is configured to decrease the heat of the vaporizer vessel.

5. The system of claim 4, wherein in response to the pressure of the vaporized material being above the set pressure range, the heater is disabled.

6. The system of claim 3, further comprising a second valve disposed in an interior volume of the vaporizer vessel; and
wherein, in response to the pressure of the vaporized material being below the set pressure range, the second valve is configured to increase the pressure of the vaporized material;
wherein, in response to the pressure of the vaporized material being above the set pressure range, the second valve is configured to decrease the pressure of the vaporized material.

7. A system, comprising:
a vaporizer vessel;
an outlet fluidly connected to the vaporizer vessel; and
a valve configured to regulate a pressure of a vaporized material exiting the vaporizer vessel such that the vaporized material is supplied to the outlet within a set pressure range.

8. The system of claim 7, further comprising at least one of a temperature sensor or a pressure sensor in electronic communication with the valve.

9. The system of claim 7,
wherein, in response to a pressure of the vaporized material being below the set pressure range, the valve is configured to increase the pressure of the vaporized material;
wherein, in response to the pressure of the vaporized material being above the set pressure range, the valve is configured to decrease a pressure of the vaporized material.

10. The system of claim 9, further comprising a heater; and
wherein, in response to the pressure of the vaporized material being below the set pressure range, the heater is configured to increase heat to the vaporizer vessel;
wherein, in response to the pressure of the vaporized material being above the set pressure range, the heater is configured to decrease the heat to the vaporizer vessel.

11. The system of claim 9, further comprising a heater; and
wherein, in response to the pressure being below the set pressure range, the heater is configured to maintain a temperature of the vaporized material;
wherein, in response to the pressure being above the set pressure range, the heater is configured to maintain a temperature of the vaporized material.

12. The system of claim 9, further comprising a second valve disposed in an interior volume of the vaporizer vessel; and
wherein, in response to the pressure of the vaporized material being below the set pressure range, the second valve is configured to increase the pressure of the vaporized material;
wherein, in response to the pressure of the vaporized material being above the set pressure range, the second valve is configured to decrease the pressure of the vaporized material.

13. A system, comprising:
a vaporizer vessel;
an outlet fluidly connected to the vaporizer vessel;
a heater configured to heat the vaporizer vessel;
a first valve configured to regulate a pressure of a vaporized material exiting the vaporizer vessel such that the vaporized material is supplied to the outlet within a first set pressure range; and
a second valve configured to regulate the pressure of the vaporized material at the outlet such that the vaporized material exits the system within a second set pressure range.

14. The system of claim 13, further comprising at least one of a temperature sensor or a pressure sensor in electronic communication with the second valve.

15. The system of claim 13,
wherein, in response to the pressure of the vaporized material being below the first set pressure range, the first valve is configured to increase the pressure of the vaporized material;
wherein, in response to the pressure of the vaporized material being above the first set pressure range, the first valve is configured to decrease the pressure of the vaporized material.

16. The system of claim 15,
wherein, in response to the pressure of the vaporized material being below the first set pressure range or the second set pressure range, the heater is configured to increase a temperature of the vaporized material;
wherein, in response to the pressure being above the first set pressure range or the second set pressure range, the heater is configured to decrease the temperature of the vaporized material.

17. The system of claim 15,
wherein, in response to the pressure of the vaporized material being below the first set pressure range or the second set pressure range, the heater is configured to maintain a temperature of the vaporized material;
wherein, in response to the pressure of the vaporized material being above the first set pressure range or the second set pressure range, the heater is configured to maintain the temperature of the vaporized material.

18. The system of claim 15,
wherein, in response to the pressure of the vaporized material being below the second set pressure range, the second valve is configured to increase the pressure of the vaporized material;
wherein, in response to the pressure of the vaporized material being above the second set pressure range, the second valve is configured to decrease the pressure of the vaporized material.

19. The system of claim 15, wherein the first valve is a mechanical valve and the second valve is an electronically actuated valve.

20. The system of claim 15, wherein the second set pressure range is a narrower range of pressures than the first set pressure range.
